(19) United States
(12) Patent Application Publication
(10) Pub. No.: US 2025/0324557 A1
(43) Pub. Date: Oct. 16, 2025

(54) LAYOUT OF STATIC RANDOM ACCESS MEMORY

(71) Applicant: UNITED MICROELECTRONICS CORP., Hsin-Chu City (TW)

(72) Inventors: Chun-Yen Tseng, Tainan City (TW); Yu-Tse Kuo, Tainan City (TW); Tsung-Hsun Wu, Kaohsiung City (TW); Shu-Ru Wang, Taichung City (TW); Liang-Wei Chiu, Tainan City (TW); Chun-Hsien Huang, Tainan City (TW); Meng-Ping Chuang, Hsinchu City (TW)

(73) Assignee: UNITED MICROELECTRONICS CORP., Hsin-Chu City (TW)

(21) Appl. No.: 18/675,186

(22) Filed: May 28, 2024

(30) Foreign Application Priority Data
Apr. 12, 2024 (TW) 113113756

(51) Int. Cl. H10B 10/00

(52) U.S. Cl. CPC H10B 10/12

(57) ABSTRACT

A layout of a static random access memory (SRAM) device includes a gate structure extending along a first direction on a substrate, a source/drain region extending along a second direction adjacent to a first side and a second side of the gate structure, a body region adjacent to a third side of the gate structure, and a notch between the gate structure and the body region.

### BACKGROUND OF THE INVENTION

### 1. Field of the Invention

The invention relates to a layout of a static random access memory (SRAM), and more particularly to a layout of forming a notch between pass gate (PG) transistor and body region.

### 2. Description of the Prior Art

An embedded static random access memory (SRAM) comprises a logic circuit and a static random access memory connected to the logic circuit. SRAM is a kind of volatile memory cell, which means it preserves data only while power is continuously applied. SRAM is built of cross-coupled inverters that store data during the time that power remains applied, unlike dynamic random access memory (DRAM) that needs to be periodically refreshed. Because of its high access speed, SRAM is also used in computer system as a cache memory.

However, as pitch of the exposure process decreases, it has been difficult for current SRAM architecture to produce desirable patterns. Hence, how to enhance the current SRAM architecture for improving exposure quality has become an important task in this field.

### SUMMARY OF THE INVENTION

According to an embodiment of the present invention, a layout of a static random access memory (SRAM) device includes a gate structure extending along a first direction on a substrate, a source/drain region extending along a second direction adjacent to a first side and a second side of the gate structure, a body region adjacent to a third side of the gate structure, and a notch between the gate structure and the body region.

According to another aspect of the present invention, a layout of a static random access memory (SRAM) device includes a first pull-up (PU) transistor, a second pull-up (PU) transistor, a first pull-down (PD) transistor, a second pull-down (PD) transistor, a first pass gate (PG) transistor, a second pass gate (PG) transistor, a first doped region between the first PG transistor and the second PG transistor, and a first notch between the first PG transistor and the first doped region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a circuit diagram of a six-transistor SRAM (6T-SRAM) cell of a SRAM of the present invention.

FIG. 2 illustrates a layout of a 6T-SRAM according to an embodiment of the present invention.

FIGS. 3-4 illustrate cross-section views for fabricating a first pass gate transistor PG1 taken along the sectional line AA′ of FIG. 2 according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

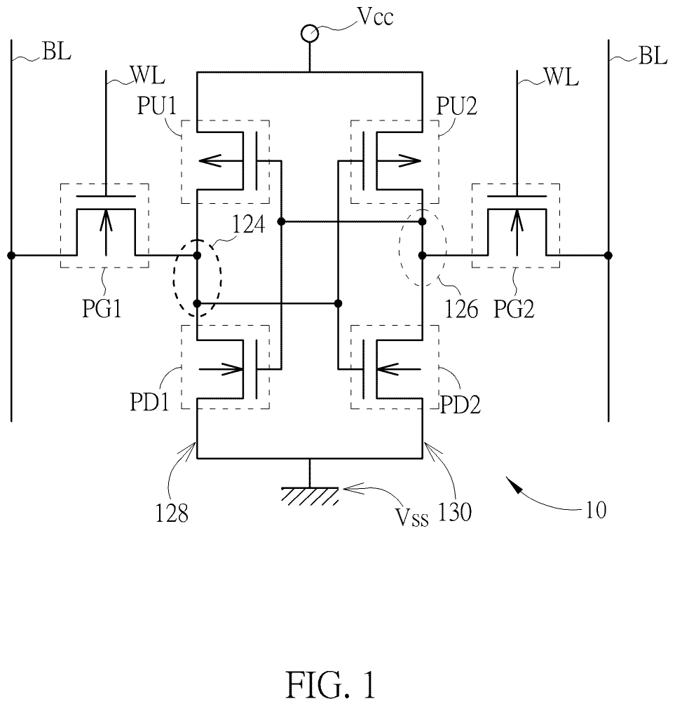

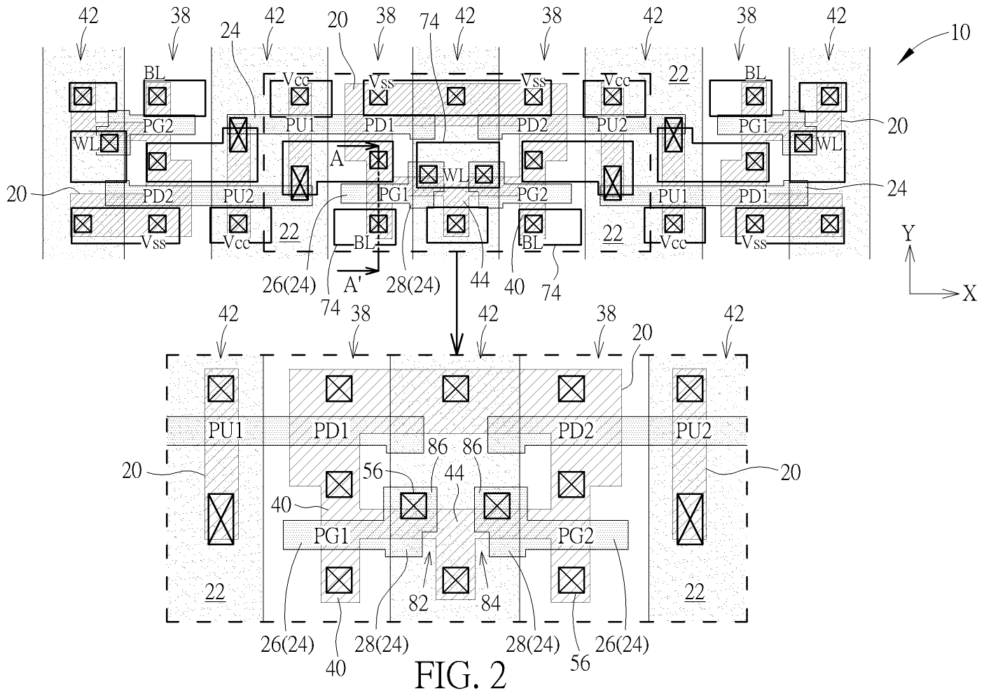

Referring to FIGS. 1-2, FIG. 1 illustrates a circuit diagram of a six-transistor SRAM (6T-SRAM) cell of a SRAM of the present invention and FIG. 2 illustrates a layout of the 6T-SRAM according to an embodiment of the present invention. As shown in FIGS. 1-2, the SRAM device of the present invention preferably includes at least one SRAM cell, each SRAM cell including a six-transistor SRAM (6T-SRAM) cell 10.

In this embodiment, each 6T-SRAM cell 10 is composed of a first pull-up transistor PU1, a second pull-up transistor PU2, a first pull-down transistor PD1, a second pull-down transistor PD2, a first pass gate transistor PG1 and a second pass gate transistor PG2. These six transistors constitute a set of flip-flops. The first and the second pull-up transistors PU1 and PU2, and the first and the second pull-down transistors PD1 and PD2 constitute a latch that stores data in the storage nodes 24 and 26. Since the first and the second pull-up transistors PU1 and PU2 act as power load devices, they can be replaced by resistors. Under this circumstance, the static random access memory becomes a four-transistor SRAM (4T-SRAM). In this embodiment, the first and the second pull-up transistors PU1 and PU2 preferably share a source/drain region and electrically connect to a voltage source Vcc, the first and the second pull-down transistors PD1 and PD2 share a source/drain region and electrically connect to a voltage source Vss.

Preferably, the first and the second pull-up transistors PU1 and PU2 of the 6T-SRAM cell 10 are composed of p-type metal oxide semiconductor (PMOS) transistors; the first and the second pull-down transistors PD1 and PD2, and first and the second pass gate transistors PG1 and PG2 are composed of n-type metal oxide semiconductor (NMOS) transistors. The first pull-up transistor PU1 and the first pull-down transistor PD1 constitute an inverter, which further form a series circuit 128. One end of the series circuit 128 is connected to a voltage source Vcc and the other end of the series circuit 128 is connected to a voltage source Vss. Similarly, the second pull-up transistor PU2 and the second pull-down transistor PD2 constitute another inverter and a series circuit 130. One end of the series circuit 130 is connected to the voltage source Vcc and the other end of the series circuit 130 is connected to the voltage source Vss.

The storage node 124 is connected to the respective gates of the second pull-down transistor PD2 and the second pull-up transistor PU2. The storage node 124 is also connected to the drains of the first pull-down transistor PD1, the first pull-up transistor PU1, and the first pass gate transistor PG1. Similarly, the storage node 126 is connected to the respective gates of the first pull-down transistor PD1 and first the pull-up transistor PU1. The storage node 126 is also connected to the drains of the second pull-down transistor PD2, the second pull-up transistor PU2, and the second access transistor PG2. The gates of the first and the second pass gate transistors PG1 and PG2 are respectively coupled to a word line (WL), and the sources are coupled to a relative data line (BL).

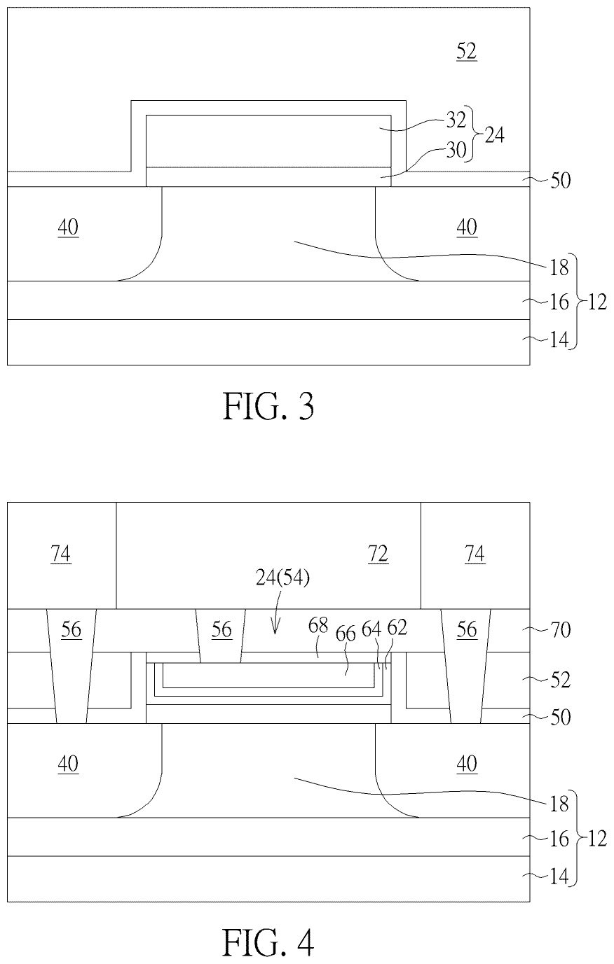

Referring to FIGS. 2-4, in which FIGS. 3-4 illustrate cross-section views for fabricating the first pass gate transistor PG1 taken along the sectional line AA′ of FIG. 2 according to an embodiment of the present invention. A shown in FIGS. 1 and 2, a substrate 12 made of silicon material such as a silicon-on-insulator (SOI) substrate is provided, in which the substrate 12 includes a first semiconductor layer 14, an insulating layer 16 disposed on the first semiconductor layer 14, and a second semiconductor layer 18 disposed on the insulating layer 16. In this embodiment, the first semiconductor layer 14 and the second semiconductor layer 18 could be made of same material or different material and could both be made of material including but not limited to for example silicon, germanium, or silicon germanium (SiGe). The insulating layer 16 disposed between the first semiconductor layer 14 and second semiconductor layer 18 preferably includes SiO₂, but not limited thereto.

It should be noted that even though the substrate 12 in this embodiment pertains to be a SOI substrate, according to other embodiment of the present invention, the substrate 12 could also be a semiconductor substrate made of a silicon substrate, an epitaxial silicon substrate, or a silicon carbide (SiC) substrate, which are all within the scope of the present invention. Next, a plurality of active areas 20 such as the regions marked by slanted lines in FIG. 2 are defined on the substrate 12, and then part of the second semiconductor layer 18 outside the active areas 20 is removed to form a shallow trench isolation (STI) 22 around the active areas 20 or the remaining second semiconductor layer 18, in which an active device or TF device is to be fabricated on the second semiconductor layer 18 surrounded by the STI 22 in the later process.

Next, a plurality of gate structures 24 are formed on the substrate 12. Viewing from a top view perspective of the first pass gate transistor PG1, the gate structure 24 is extending along a first direction such as X-direction on the substrate 12, in which the gate structure 24 overall has a T-shape or more specifically a laid down T-shape or T-shape inverted at 90 degrees. Preferably, the T-shape includes a longer horizontal portion 26 and a shorter vertical portion 28, in which the horizontal portion 26 extends along the X-direction while the vertical portion 28 extends along the Y-direction on the substrate 12. It should be noted that even the gate structure 24 is shown to have a T-shape in this embodiment, according to other embodiment of the present invention the gate structure 24 under top view perspective could also have an L-shape, which is also within the scope of the present invention.

Preferably, the formation of the gate structure 24 could be accomplished by a gate first process, a high-k first approach from gate last process, or a high-k last approach from gate last process. Since this embodiment pertains to a high-k last approach, a gate dielectric layer 30 or interfacial layer made of silicon oxide, a gate material layer 32 preferably made of polysilicon, and a selective hard mask (not shown) could be formed sequentially on the substrate 12, and a pattern transfer process is then conducted by using a patterned resist (not shown) as mask to remove part of the gate material layer 32 and part of the gate dielectric layer 30 through single or multiple etching processes. After stripping the patterned resist, a gate structure 24 composed of a patterned gate dielectric layer 30 and patterned gate material layer 32 is formed on the substrate 12.

Next, at least a spacer (not shown) is formed on sidewalls of the gate structure 24. In this embodiment, the spacer could be a single spacer or a composite spacer as the spacer could further include an offset spacer (not shown) and a main spacer (not shown). The offset spacer and the main spacer are preferably made of different materials while the offset spacer and main spacer could all be selected from the group consisting of SiO₂, SiN, SiON, and SiCN, but not limited thereto.

Next, a patterned mask (not shown) such as a patterned resist is formed to cover the region 42 including part of the vertical portion 28 and part of the STI 22 adjacent to the vertical portion 28, and then an ion implantation process is conducted to form a doped region in the region 38 or active area 20 or the substrate 12 adjacent to two sides of the horizontal portion 26 of the gate structure 24 serving as a source/drain region 40. The patterned mask is then removed thereafter. In this embodiment, the ion implantation process conducted at this stage preferably implants n-type dopants into the substrate 12 such that the source/drain region 40 formed is preferably a n+ region.

Next, another patterned mask (not shown) such as a patterned resist is formed to cover part of the devices on the region 38 including the horizontal portion 26 and part of the vertical portion 28 of the gate structure 24 of the PG1 and the source/drain region 40, and then an ion implantation process is conducted to form another doped region serving as a body region 44 in the region 42 or active area 20 or the substrate 12 adjacent to the vertical portion 28. In this embodiment, the ion implantation process conducted at this stage preferably implants p-type dopants into the substrate 12 so that the body region 44 is preferably a p+ region. In this embodiment, the regions 38 and the regions 42 are defined extending alternately along the Y-direction, in which the regions 38 are blank or non-dotted areas extending along the Y-direction as shown in FIG. 2 while the regions 42 are dotted areas also extending along the Y-direction. Preferably, the regions 38 include active areas 20 having n-type or n+dopants while the regions 42 include active areas 20 having p-type or p+dopants.

Next, a selective salicide process could be conducted to form a silicide (not shown) on the surface of the source/drain region 40 and the body region 44, a contact etch stop layer (CESL) 50 made of silicon nitride could be formed on the substrate 12 to cover the gate structure 24, and then an inter-layer dielectric (ILD) layer 52 is formed on the CESL 50.

Next, as shown in FIG. 4, a planarizing process such as a chemical mechanical polishing (CMP) process is conducted to remove part of the ILD layer 52 and part of the CESL 50 so that the top surfaces of the gate structure 24, the CESL 50, and ILD layer 52 are coplanar.

Next, a replacement metal gate (RMG) process is conducted to transform the gate structure 24 into metal gate 54. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layer 32 from gate structure 24 for forming a recess (not shown) in the ILD layer 52. Next, a high-k dielectric layer 62, a work function metal layer 64, and a low resistance metal layer 66 are formed in the recess, and a planarizing process such as CMP is conducted to remove part of low resistance metal layer 66, part of work function metal layer 64, and part of high-k dielectric layer 62 to form metal gate. In this embodiment, the gate structure 24 or metal gate 54 fabricated through high-k last process of a gate last process preferably includes an interfacial layer or gate dielectric layer 30, a U-shaped high-k dielectric layer 62, a U-shaped work function metal layer 64, and a low resistance metal layer 66 as the high-k dielectric layer 62, the work function metal layer 64, and the low resistance metal layer 66 together serving as a gate electrode for each transistor or each device.

In this embodiment, the high-k dielectric layer 62 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 64 is formed for tuning the work function of the metal gate in accordance with the conductivity of the device. For an NMOS transistor, the work function metal layer 64 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 64 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low-resistance metal layer 66 may include copper (Cu), aluminum (Al), titanium aluminum (TiAl), cobalt tungsten phosphide (CoWP) or any combination thereof.

Next, part of the high-k dielectric layer 62, part of the work function metal layer 64, and part of the low resistance metal layer 66 are removed to form a recess (not shown), and a hard mask 68 is then formed into the recess so that the top surfaces of the hard mask 68 and ILD layer 52 are coplanar. The hard mask 68 could be made of material including but not limited to for example SiO₂, SiN, SiON, SiCN, or combination thereof.

Next, a contact plug formation process could be conducted by forming another dielectric layer 70 on the ILD layer 52, conducting a photo-etching process by using a patterned mask (not shown) as mask to remove part of the dielectric layer 70 and part of the hard mask 68 directly on top of the gate structure 24 and part of the ILD layer 52 and part of the CESL 50 adjacent to the gate structure 24 for forming contact holes (not shown) exposing top surface of the gate structure 24, the source/drain region 40 and body region 44. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 56 electrically connecting the gate structure 24, the source/drain region 40, and the body region 44.

Next, a metal interconnective process could be conducted by first forming an inter-metal dielectric (IMD) layer 72 on the dielectric layer 70 and then conducting one or more photo-etching process to remove part of the IMD layer 72 for forming contact holes. Next, conductive materials are deposited into the contact hole and a planarizing process such as CMP is conducted to form a metal interconnections 74 directly contacting the contact plugs 56 underneath. Similar to the contact plugs 56 formed previously, each of the metal interconnections 74 could all be formed in the IMD layer 72 through single damascene or dual damascene process. For instance, each of the metal interconnections 74 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. This completes the fabrication of a semiconductor device according to an embodiment of the present invention.

Referring again to FIG. 2, the top portion of FIG. 2 illustrates a layout of a plurality of 6T-SRAMs according to an embodiment of the present invention and the bottom portion of FIG. 2 illustrates an enlarged view of the first pass gate transistor PG1 and the second pass gate transistor PG2 from a single 6T-SRAM. As shown in FIG. 2, the 6T-SRAM principally includes a first pull-up transistor PU1, a second pull-up transistor PU2, a first pull-down transistor PD1, a second pull-down transistor PD2, a first pass gate transistor PG1 and a second pass gate transistor PG2.

In the region where the first pass gate transistor PG1 and the second pass gate transistor PG2 are located, the first pass gate transistor PG1 preferably includes a gate structure 24 extending along the X-direction on the substrate 12 and a source/drain region 40 extending along the Y-direction on a first side such as left side of the gate structure 24 and on a second side such as right side of the gate structure 24. Similarly, the second pass gate transistor PG2 includes a symmetrical gate structure 24 extending along the X-direction on the substrate 12 and a source/drain region 40 extending along the Y-direction adjacent to two sides of the gate structure 24. Preferably, a body region 44 is disposed between the first pass gate transistor PG1 and the second pass gate transistor PG2, a first notch 82 is disposed between the first pass gate transistor PG1 and the body region 44, and a second notch 84 is disposed between the second pass gate transistor PG2 and the body region 44, in which the body region 44 has a substantially cross shape under top view perspective.

It should be noted that the first notch 82 could be defined as a distance measured from an edge of the first pass gate transistor PG1 to an edge of the body region 44. Alternatively, the first notch 82 could also be defined as an indented side of the vertical portion 28 of the gate structure 24 of the first pass gate transistor PG1, such as the portion formed by two sidewalls of the indentation on right side of the vertical portion 28. In this embodiment, an extending portion 86 is extended on right side of the vertical portion 28 of the gate structure 24 of the first pass gate transistor PG1 and the recessed region or indentation directly below the extending portion 86 preferably forms the first notch 82 and exposes the body region 44 underneath.

Similarly, the second notch 84 could be defined as a distance measured from an edge of the second pass gate transistor PG2 to an edge of the body region 44. Alternatively, the second notch 84 could also be defined as an indented side of the vertical portion 28 of the gate structure 24 of the second pass gate transistor PG2, such as the portion formed by two sidewalls of the indentation on left side of the vertical portion 28. In this embodiment, an extending portion 86 is extended on left side of the vertical portion 28 of the gate structure 24 of the second pass gate transistor PG2 and the recessed region or indentation directly below the extending portion 86 preferably forms the second notch 84 and exposes the body region 44 underneath.

Moreover, three contact plugs 56 (each labeled by a cross) are disposed on the vertical portion 28 and source/drain region 40 adjacent to two sides of the gate structures 24 of each of the first pass gate transistor PG1 and the second pass gate transistor PG2. An additional contact plug 56 is further disposed on the body region 44 between the gate structure 24 of the first pass gate transistor PG1 and the gate structure 24 of the second pass gate transistor PG2.

In this embodiment, the contact plug 56 disposed directly on top of the vertical portion 28 of the gate structure 24 of the first pass gate transistor PG1 also overlaps part of the active area 20 directly under the gate structure 24 and the contact plug 56 disposed directly on top of the vertical portion 28 of the gate structure 24 of the second pass gate transistor PG2 on the other side also overlaps part of the active area 20 under the gate structure 24 as both contact plugs 56 are connected to each other through the metal interconnection 74 above.

Overall, the present invention discloses a 6T-SRAM layout, which preferably retracts part of the gate structure 24 of the first pass gate transistor PG1 and part of the gate structure 24 of the second pass gate transistor PG2 by forming a notch on one side of the vertical portion 28 of each gate structure 24 so that the adjacent body region 44 would reveal a substantially cross-shape profile under top view perspective. According to a preferred embodiment of the present invention, the formation of the aforementioned notch or notches could increase the process window between gate structures and contact plugs and as the overall area of silicide on the body region 44 increases, resistance on each of the pass gate transistors could also be reduced substantially.

Moreover, upper level metal interconnections such as word lines WL from the aforementioned embodiment could connect adjacent transistors and/or contact plugs 56 directly on top of the vertical portions 28 of gate structures 24 from each of the pass gate transistors PG1 or PG2 could overlap the active area 20 directly under the gate structures 24 so that overall area of the memory unit could be reduced significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout of a static random access memory (SRAM) device, comprising:
a gate structure extending along a first direction on a substrate;
a source/drain region extending along a second direction adjacent to a first side and a second side of the gate structure;
a body region adjacent to a third side of the gate structure; and
a notch between the gate structure and the body region.

2. The layout of a SRAM device of claim 1, wherein the notch exposes the body region.

3. The layout of a SRAM device of claim 1, wherein the source/drain region and the body region comprise different conductive type.

4. The layout of a SRAM device of claim 2, wherein gate structure comprises a T-shape.

5. The layout of a SRAM device of claim 4, wherein the T-shape comprises:
a horizontal portion extending along the direction; and
a vertical portion extending along the second direction.

6. The layout of a SRAM device of claim 1, wherein the vertical portion comprises the notch.

7. The layout of a SRAM device of claim 1, wherein the gate structure comprises a L-shape.

8. The layout of a SRAM device of claim 1, further comprising:
a first contact plug on the gate structure;
a second contact plug and a third contact plug on the source/drain region; and
a fourth contact plug on the body region.

9. A layout of a static random access memory (SRAM) device, comprising:
a first pull-up (PU) transistor;
a second pull-up (PU) transistor;
a first pull-down (PD) transistor;
a second pull-down (PD) transistor;
a first pass gate (PG) transistor;
a second pass gate (PG) transistor;
a body region between the first PG transistor and the second PG transistor; and
a first notch between the first PG transistor and the body region.

10. The layout of a SRAM device of claim 9, wherein the first notch exposes the body region.

11. The layout of a SRAM device of claim 9, further comprising a second notch between the second PG transistor and the body region.

12. The layout of a SRAM device of claim 11, wherein the second notch exposes the body region.

13. The layout of a SRAM device of claim 9, wherein a source/drain region of the first PG transistor and the body region comprise different conductive type.

14. The layout of a SRAM device of claim 9, further comprising:
a first contact plug on a first gate structure of the first PG transistor;
a second contact plug on a second gate structure of the second PG transistor; and
a metal interconnection connecting the first contact plug and the second contact plug.
